(19) United States
(12) Patent Application Publication
(10) Pub. No.: US 2011/0215821 A1
(43) Pub. Date: Sep. 8, 2011

(54) EMITTER WHEEL ASSEMBLY

(75) Inventor: Orlando Da Mota PAVAN, Sao Paulo (ES)

(73) Assignee: SABO INDUSTRIA E COMERCIO DE AUTOPECAS LTDA, Sao Paulo (ES)

(21) Appl. No.: 13/042,993

(22) Filed: Mar. 8, 2011

(30) Foreign Application Priority Data
Mar. 8, 2010 (ES) PI 1.001.408-0

(51) Int. Cl. G01R 27/26

(52) U.S. Cl. 324/686

(57) ABSTRACT

This abstract refers to an invention patent related to an emitter wheel assembly, more particularly with the association of a special sensitizer ring set (1) and a special capacitive sensor (20), and an electrostatic device (80) for recharging the ring, the said ring being able to generate an electric field (40), provided with temporary initial charge and being rechargeable by the electrostatic recharging device (80), and the capacitive sensor being able to be sensitized by the electric field (40); the said assembly being developed for particularly automotive applications and/or related applications requiring a device for identifying and monitoring the rotations, positions, angulations, speeds an other attributes of a rotating part, such device having low cost and long useful life.

This descriptive report refers to an invention patent related to an emitter wheel assembly constituted by the association of a special sensitizer ring and a special capacitive sensor, and a ring recharging device, the said ring being able to generate an electric field, with temporary initial electric charge, and being rechargeable by a recharging device during its operation, and the capacitive sensor being able to be sensitized by the electric field; the said assembly being developed for particularly automotive applications and/or related applications requiring a device for identifying and monitoring the rotations, positions, angulations, speeds an other attributes of a rotating part, such device having low cost and long useful life.

### STATE OF THE ART

Several equipments have rotating parts, such as shafts and others, which require having their rotation system monitored and identified, so that their operation occur within the desired parameters and/or to meet other purposes. For this aim, these rotating parts are associated with sensor sets, usually and mainly constituted: by sensitizer device(s) assembled around the rotating part; by appropriate sensor device(s) assembled adjacent to the sensitizer device(s); by means of sensitization, as, for example, magnetic fields generated, for example, by sensitizer device(s), which sensitizes the sensor(s) that, once sensitized, is (are) switched, generating signal(s); and by a dedicated electronic circuit able to process the signal(s) generated.

Sets of this type are commonly used in automotive industry, as occurs, for example, in electronic fuel injection systems, to monitor the crankshaft position, critical to the management and smooth operation of the engine, rendering less fuel consumption, fewer environmental emissions, lower noise intensity, and others. Hall Effect, AMR, or GMIR magnetic sensors are commonly used in this application.

However, the high cost is one of the restrictions for this Hall sensor component for automotive applications. In fact, cars comprise a large number of items and generally have a relatively high cost. For this reason, besides the required technical quality, the designs of their constituent items always pursue a cost reduction, so that, overall, these items can lead to a lower cost for the vehicle as a whole.

### PURPOSES OF THE INVENTION

Therefore, in order to overcome the above-mentioned problem, it was researched the possibility of using a capacitive rotation sensor assembly that could meet the automotive application technical specifications, with a much lower cost.

The capacitive sensors available in the market, also known as proximity sensors, are essentially constituted by two conductive terminals, negative and positive, and a dielectric separating the terminals. These sensors apply the concept according to which, when any body approaches the sensing face, there is a change in dielectric behavior that, in turn, varies the amount of charges present in the capacitive element, causing the sensor signal to be switched. Thus, in this automotive application, it was found that the manner in which the sensitizer ring interferes with the conventional capacitive sensor seemed technically complicated.

Therefore, the first technological challenge to be overcome was developing a special sensitizer ring able to interfere with a capacitive sensor differently than what is provided in conventional capacitive sensors systems known in the market. Considering this, it was prospected the development of an electrically charged sensitizer ring able to generate an electric field, and a special capacitive sensor able to be sensitized by this electric field, so that a signal could be generated.

Hence, one of the purposes of the invention, subject of this patent, consists in providing a sensitizer ring similar to that of “state of the art”, however exploring the effect of an electric field emitted by this sensitizer ring or by elements linked to it, which sensitizes a special capacitive sensor.

Another purpose consists in providing a special capacitive sensor able to “read” the specific electric field generated by the sensitizer ring or by elements linked to it, and generating a signal.

For this aim, in a possibility of embodiment, the line of development for this sensitizer ring started at developing a special material able to store electric charges (superficial or via electric dipoles) and developing a process for application on the sensitizer ring, along with the electric charging process for the dielectric material.

During the initial assessment of development, it was found that the electric charging process for the dielectric material could be accomplished by using the corona ionization process of the prior art, as mentioned, for example, in Patents U.S. Pat. No. 3,924,324 and U.S. Pat. No. 3,702,493 or by using the electric discharges process of the prior art, as mentioned, for example, in U.S. Pat. No. 4,441,038.

Although being available in the market materials able to store electric charges, and processes able to incorporate such charges (electric charging) into materials, which could be used in developing the electrically charged sensitizer ring for this emitter wheel assembly, it was found that another technological challenge, particularly in automotive applications, would have to be overcome, namely the presence of a natural physical effect that always seeks a balance amongst electric charges. In this case, the electric charges dispersed in the environment interact with the charges deposited in the dielectric material incorporated into the sensitizer ring, neutralizing the charges deposited.

Therefore, by the effect of electrical neutralization, the sensitizer ring loses the intensity of electric charges over time, until it no longer generates the electric signal through which the capacitive sensor can act, thus losing its function. It was found that materials known in the market, electrically charged by the above-mentioned processes, stand no more than one (1) year, when kept in an open environment, thus being not technically feasible for an industrial application, particularly in the automotive area, which requires more than ten (10) years of durability.

Thus, another technological challenge to be over-come was to make possible a product whose useful life initially would not attend the industrial application, particularly in the automotive area, which requires more than ten (10) years of durability. Consequently, another purpose of this patent consists in providing an electrically charged sensitizer ring that generates an electric field that sensitizes the special capacitive sensor, while being able to maintain the electric charge for a period appropriate to meet industrial applications, particularly in the automotive area, which requires more than ten (10) years of durability and low cost.

### SUMMARY OF THE INVENTION

Hence, considering and aiming to overcome the above-mentioned problems, as well as aiming to meet the purposes enumerated, it was developed the emitter wheel assembly, subject of this invention patent, substantially constituted by a annular body electrically charged or incorporating electrically charged elements, which is assembled jointly around the rotating part to be monitored, which generates an electric field, which sensitizes a special capacitive sensor, the said ring initially having temporary electric charge and being rechargeable by friction during its operation; by an electrostatic device for recharging the sensitizer ring, substantially composed by a friction element that causes friction on the ring during its operation; by a special capacitive sensor substantially constituted by terminals in the form of two parallel metallic electrodes arranged to act as an “antenna” that captures the electric signal generated by the sensitizer ring; and by an electronic circuit that processes the signal.

This form of construction of the emitter wheel assembly, particularly its sensitizer ring set, solves the drawbacks observed with conventional rotation sensors, particularly for automotive use, because this assembly features an efficient operation, lower cost than hall sensors commonly used in automotive industry, and useful life able to meet the above-ten-years useful life required for automotive applications.

### DESCRIPTION OF THE FIGURES

The emitter wheel assembly, subject of this patent, is shown by the attached figures, for purposes merely illustrative and non-restrictive, in which:

FIGS. 1A and 1B contain schematic views of the emitter wheel assembly, respectively indicating how it is assembled on a shaft, and featuring a detail on the assembly, showing a sector of the sensitizer ring with the indication of the charges and the respective special capacitive sensor;

FIGS. 2A, 2B, 2C, 2D show schematic views of several possibilities for constructing the sensitizer ring;

FIGS. 3 and 4 show schemes of electric charging processes, corona and by contact, for the dielectric material constituent of the electrically chargeable elements of the sensitizer ring, the said processes, according to the invention, being intended to deposit an initial electric charge on the surface of the said electrically chargeable elements;

FIG. 5 shows a view of the emitter wheel assembly, emphasizing a possibility for positioning the friction element(s) constituent of the device for recharging the sensitizer ring;

FIG. 6 shows schemes for the special capacitive sensor comprised by the innovation; and

FIG. 7 contains a detail showing the distance between the electrically chargeable elements of the sensitizer ring and the metallic electrodes of the sensor.

### DETAILED DESCRIPTION OF THE INVENTION BASED ON THE FIGURES

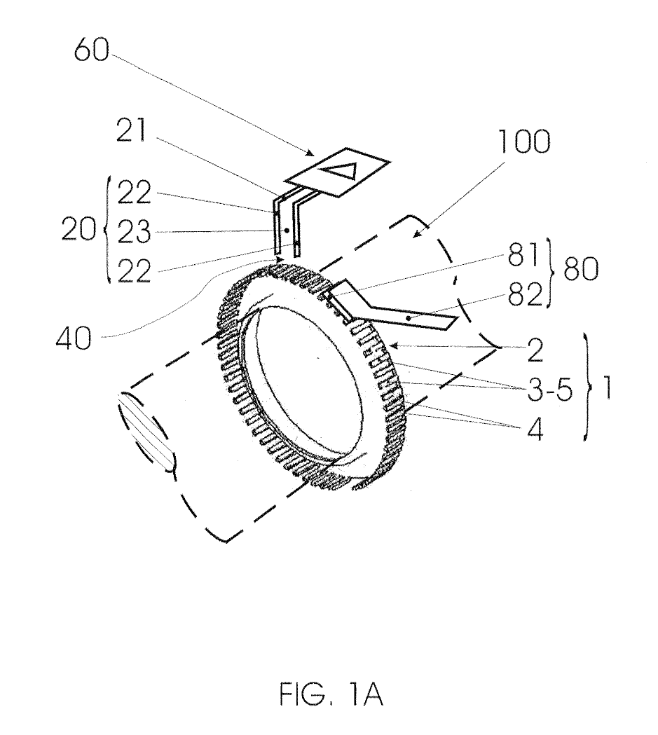

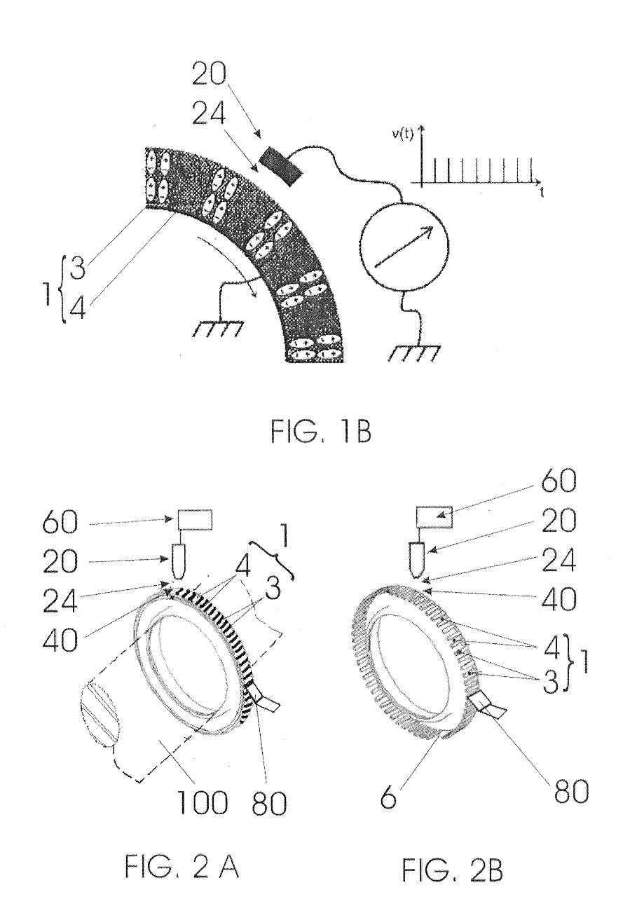

In accordance with the illustrations featured by the above-described figures, the emitter wheel assembly, subject of this invention patent, aims to monitor rotating parts, particularly in automotive applications, being essentially constituted (FIG. 1): by a sensitizer ring 1, assembled jointly and around the rotating part 100 to be monitored; by a sensor 20, assembled adjacent to the sensitizer ring 1; by means of sensitization 40, which interacts with (between) the sensitizer ring 1 and the sensor 20, for generating an electric signal 21; and by an electronic processing circuit 60 that processes the signal 21.

In this invention, the sensitizer ring 1 is an electrically charged sensitizer ring able to generate an electric field 40, which sensitizes the sensor 20; the said ring having temporary initial electric charge and being rechargeable during its operation.

The emitter wheel assembly comprises additionally an electrostatic device 80 for recharging the sensitizer ring 1, during its operation.

The sensor 20 is a special capacitive sensor substantially comprising two parallel metallic electrodes (wires) 22 that capture the electric field originated by the sensitizer ring 1, generating the signal 21, and comprising an appropriate opening 23 between the electrodes.

The mean of sensitization 40, which provides the interaction between the sensitizer ring 1 and the special capacitive sensor 20, consequently generating the electric signal 21, is the electric field 40 produced by the electric charge present on the electrically charged sensitizer ring 1.

The electronic circuit 60 is a circuit suitable for processing the electric signal 21 as required, being able, for example, to filter, amplify, convert to digital signal or others, according to the characteristics of the rest of the assembly with which the emitter wheel assembly contributes.

In detail, the sensitizer ring 1 is essentially constituted (FIG. 1): by an annular body 2, made from metallic or polymeric material, having an internal diameter appropriate to be assembled jointly around the rotating part (shaft or rotating body) 100 to be monitored, and having a peripheral surface; by electrically chargeable peripheral elements 3 and non-electrically chargeable spaces 4, being integrated or not to the external face of the peripheral surface of the body 2, and regularly interleaved with each other.

The electrically chargeable peripheral elements 3 may consist of portions of a dielectric material 5 applied, or adhered, or deposited in formats appropriate for the system, and interleaved with the non-electrically chargeable spaces 4 regularly interleaved with each other. Depending on the application, the said sensitizer ring 1 may be optionally implemented in some variants.

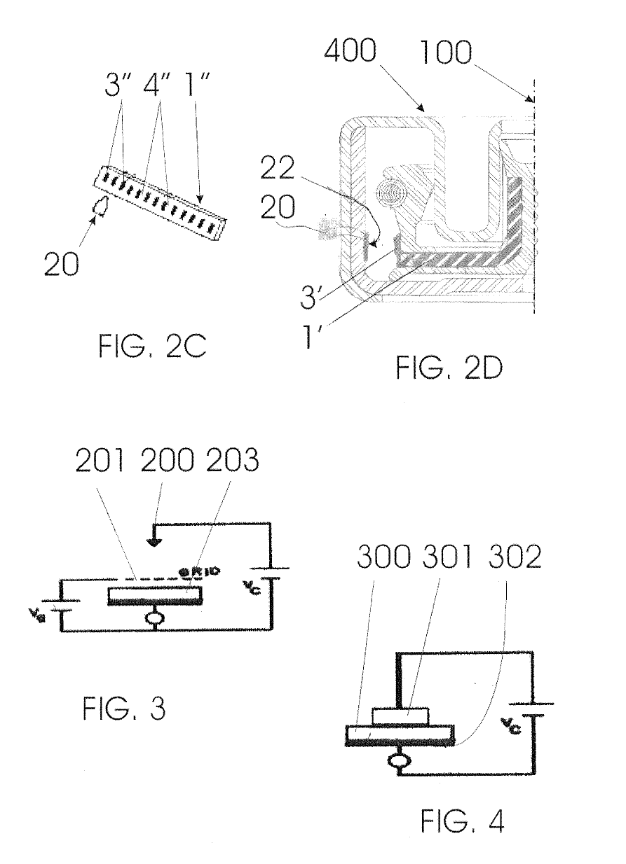

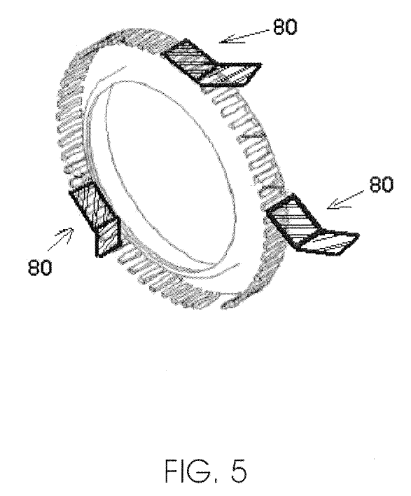

Thus, in a possibility of embodiment (FIG. 2A), the sensitizer ring 1 may be continuous, that is, composed by electrically chargeable peripheral portions 3 and non-electrically chargeable peripheral portions 4 arranged at regular intervals throughout the periphery.

Optionally, (FIG. 2B) the sensitizer ring 1 may be segmented, that is, having portion(s) 6 differentiated in relation to the other portions 3 and 4.

So that the electrically chargeable material of the annular body generates an independent electric field, that is, its composition to becomes to have electric charges, this material should be treated by any corona (FIG. 3) or electric discharge (FIG. 4) charging processes of the types from the above-mentioned or similar patents.

Therefore, in electric charging by corona (FIG. 3), a probe 200, submitted to a high voltage between −5 to −15 kV, radiates ions to a “Grid” 201 having voltage below 1 kV, and it radiates ions to the surface of the electrically chargeable material 203, which is grounded.

In electric charging by contact or electric discharge (FIG. 4), the electrically chargeable material 300 is arranged between two metallic plates 301, 302 through which a high voltage, between −5 to −15 kV, is applied to the material surface.

However, in this invention, the electric charging process of the sensitizer ring, at manufacturing level, has the purpose of incorporating an initial electric charge in the dielectric material 5 constituent of the electrically chargeable peripheral elements 3, of the sensitizer ring 1, being the said initial charge aimed to allow the operation of the emitter wheel assembly at the start of its useful life, since, as seen, the charge deposited in the dielectric material, by the above-mentioned corona and contact processes, interacts with charges present on the environment being neutralized within a period of time inadequate for industrial applications, particularly in the automotive area, which requires more than ten (10) years of durability. For this reason, in this invention, it was chosen a sensitizer ring 1 incorporating two types of charges: a temporary initial starting charge, provided by the usual corona or contact processes above-mentioned, applied at the manufacturing of the ring; and a non-permanent and renewable charge provided by the electrostatic device 80 that recharges the sensitizer ring 1 during its operation.

The sensitizer ring 1, particularly its electrically chargeable elements 3, is (are) selected so that the ring has a residual charge of at least 50 Volts.

The electrostatic device 80, for recharging the sensitizer ring 1 during its operation, is substantially constituted (FIG. 1) by a friction element 81, assembled adjacent to the sensitizer ring and in order to allow its interference with the electrically chargeable elements 3 arranged along the periphery of the ring.

In a possibility of embodiment, the friction element 81 is assembled at the end of a laminar spring 82, whose opposed end is assembled on a surface adjacent to the ring, the said spring being arranged to press the friction element 81 with a constant force against the periphery of the sensitizer ring 1 that comprises the electrically chargeable elements 3.

In another possibility of embodiment, the friction element 81 is simply assembled adjacent to the sensitizer ring 1, and in order to have interference with the periphery of the said ring, which comprises the electrically chargeable elements 3.

The friction element 81 is composed by appropriate polymeric, ceramic, or composite material that allows the accumulation of negative charges over the electrically chargeable elements 3 of the sensitizer ring 1.

One or several friction element(s) 81 may be assembled around the sensitizer ring 1.

Thereby, the friction element(s) 81 is (are) responsible for recharging superficially the dielectric material constituent of the electrically chargeable elements 3, of the sensitizer ring 1.

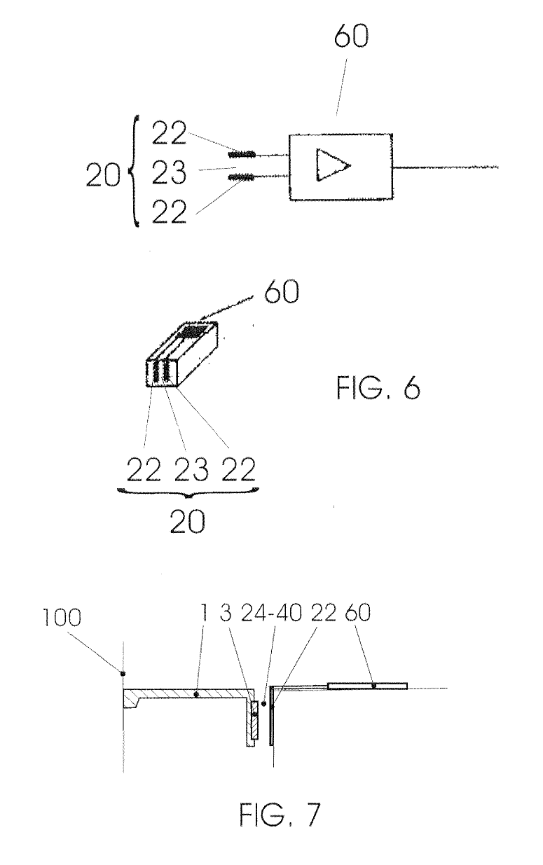

The special capacitive sensor 20 (FIG. 6), which is a constituent part of the emitter wheel assembly, is substantially constituted by two parallel electrodes 22 that capture the electric field originated by the sensitizer ring 1. The opening 23 between the metallic electrodes 22 is calculated so that the distance between the electrodes generates signals with a phase-lag of 180°, which, in turn, are amplified and subsequently subtracted, resulting in an output signal increase as well as a potential noise reduction, due to the phase-lag.

In another possibility of embodiment (not shown), the sensor 20 is composed by only two metallic electrodes, being sensitized by the electric field of the sensitizer ring, being the resulting signal sent directly to the ECU through a shielded pair twisted wires, the electronic processing circuit being embedded in the ECU itself.

The distance 24 between the electrode(s) and the electrically chargeable elements 3, of the sensitizer ring 1, is approximately 2 mm (FIG. 7).

The emitter wheel assembly, built in accordance with the present invention, operates as follows: When the rotating part 100 starts moving, the electrically chargeable elements 3 and the non-electrically chargeable spaces 4, of the periphery of the sensitizer ring 1, pass sequentially near the electrodes 22 of the special capacitive sensor 20, causing the said electrodes 22 to be alternately sensitized by the electric fields 40 of the electrically chargeable elements 3, and non-sensitized by the non-electrically chargeable spaces 4, so generating the (analog) signals 21 that are processed by the circuit 60.

At the start of the useful life of the sensitizer ring 1, the electric field 40 results from the electric charge deposited by corona or contact process, at manufacturing level. With the continued use of the sensitizer ring 1 and the presumable decrease in the charge initially deposited, caused by interaction with the environment, the electrostatic device 80, for recharging the sensitizer ring 1, begins to recharge by friction the electrically chargeable elements 3 of the sensitizer ring 1, so keeping it operative.

According to the basic embodiment above described, the emitter wheel assembly, subject of this patent, may comprise modifications concerning materials, dimensions, construction details, and/or functional configuration, without diverging from the scope of the protection requested.

Accordingly, the sensitizer ring 1 may be in the form of a continuous ring defined by the existence of electrically chargeable elements 3 and non-electrically chargeable spaces 4, interleaved. Optionally, the annular body may be discontinuous, dented, so that the teeth constitute the electrically chargeable elements 3, and the openings between the teeth constitute the non-electrically chargeable spaces 4. The first version of the sensitizer ring 1, with continuous body, features the advantage of greater rigidity, so being more robust. The dented wheel features the advantage of not requiring a step for the segmentation process of the electrically chargeable elements, because they follow the dented format of said continuous annular body.

In an optional embodiment (FIG. 2D), to avoid the neutralization of the charges existent in the dielectric material that composes the electrically chargeable elements 3′, the sensitizer ring is an enclosed sensitizer ring 1′, assembled into a shielded, electrically insulated environment, so as not to lose charge to the environment. As a non-restrictive example, FIG. 2D shows the enclosed sensitizer ring 1′, assembled inside a shielded retainer 400 and provided with the electrically chargeable peripheral elements 3′ arranged on the surface of the ring, and adjacent to the retainer sealing lip, being the electrodes 22 of the sensor device 20 assembled on the internal face of the shielded housing of said retainer. In this case, the emitter wheel assembly does not have the recharging element.

Optionally, instead of the sensitizer ring, a continuous linear element 1″ is provided, incorporating the electrically chargeable elements 3″ and the non-electrically chargeable spaces 4″ interleaved and adjacent to the sensor 20.

1) “EMITTER WHEEL ASSEMBLY”, essentially constituted: by a sensitizer ring (1), assembled jointly and around a rotating part (100) to be monitored; by a sensor (20), assembled adjacent to the sensitizer ring (1); by means of sensitization (40), which interacts with (between) the sensitizer ring (1) and the sensor (20), for generating an electric signal (21); and by an electronic processing circuit (60) that processes the signal (21), characterized by the sensitizer ring (1) being an electrically charged sensitizer ring able to generate an electric field (40), which sensitizes the sensor (20); the said ring may have an initial electric charge and being rechargeable during its operation, and the said emitter wheel assembly comprises additionally an electrostatic device (80) for recharging the sensitizer ring (1) during its operation.

2) “EMITTER WHEEL ASSEMBLY”, in accordance with claim 1, being the sensitizer ring (1) essentially constituted: by an annular body (2), made from metallic or polymeric material, having an internal diameter appropriate to be assembled jointly around the rotating part (100) to be monitored, and having a peripheral surface, characterized by electrically chargeable peripheral elements (3) and non-electrically chargeable spaces (4) being integrated or not to the external face of the peripheral surface of the body 2, and regularly interleaved with each other.

3) “EMITTER WHEEL ASSEMBLY”, in accordance with claim 2, characterized by the electrically chargeable peripheral elements (3) being allowed to consist of portions of a dielectric material (5) applied, or adhered, or deposited in formats appropriate for the system, and interleaved with the non-electrically chargeable spaces (4) regularly arranged in relation with each other, on the ring periphery.

4) “EMITTER WHEEL ASSEMBLY”, in accordance with claim 1, characterized by the sensitizer ring (1) being allowed to be continuous, composed by electrically chargeable peripheral portions (3) and non-electrically chargeable peripheral portions (4) arranged at regular intervals throughout the periphery.

5) “EMITTER WHEEL ASSEMBLY”, in accordance with claim 1, characterized by the sensitizer ring (1) having a discontinuous, dented surface, so that the teeth constitute the electrically chargeable elements (3), and the openings between the teeth constitute the non-electrically chargeable spaces (4).

6) “EMITTER WHEEL ASSEMBLY”, in accordance with claim 1, characterized by the sensitizer ring (1) being allowed to be segmented, having portion(s) (6) differentiated in relation to the other portions (3) and (4).

7) “EMITTER WHEEL ASSEMBLY”, in accordance with claim 1, characterized by the sensitizer ring (1) incorporating two types of charges: a temporary initial starting charge, provided by the usual corona or contact processes applied at the manufacturing of the ring; and a non-permanent and renewable charge provided by the electrostatic device (80) that recharges the sensitizer ring (1) during its operation.

8) “EMITTER WHEEL ASSEMBLY”, in accordance with claim 1, characterized by the sensitizer ring (1), particularly its electrically chargeable elements (3), being selected so that the ring has a residual charge of at least 50 Volts.

9) “EMITTER WHEEL ASSEMBLY”, in accordance with claim 1, characterized by the electrostatic device (80) for recharging the sensitizer ring (1) during its operation, being substantially constituted by one or more friction element(s) (81), assembled adjacent to the sensitizer ring and in order to allow its interference with the electrically chargeable elements (3) arranged along the periphery of the ring.

10) “EMITTER WHEEL ASSEMBLY”, in accordance with claim 9, characterized by the friction element (81) being assembled at the end of a spring (82), whose opposed end is assembled on a surface adjacent to the ring, the said spring pressing the friction element (81) with a constant force against the periphery of the sensitizer ring (1) that comprises the electrically chargeable elements (3).

11) “EMITTER WHEEL ASSEMBLY” in accordance with claim 9, characterized by the friction element (81) being simply assembled adjacent to the sensitizer ring (1) and in order to have interference with the periphery of the said ring that comprises the electrically chargeable elements (3).

12) “EMITTER WHEEL ASSEMBLY”, in accordance with claim 9, characterized by the friction element (81) being composed by an appropriate material that allows the accumulation of negative charges over the electrically chargeable elements (3) of the sensitizer ring (1).

13) “EMITTER WHEEL ASSEMBLY”, in accordance with claim 9, characterized by one or several friction element(s) (81) being allowed to be assembled around the sensitizer ring (1).

14) “EMITTER WHEEL ASSEMBLY”, in accordance with claim 2, characterized by the a distance (24) between the electrically chargeable elements (3) of the sensitizer ring (1) and at least one electrode (22) of the sensor (20) being approximately 2 mm.

15) “EMITTER WHEEL ASSEMBLY”, in accordance with claim 2, characterized by the electrically chargeable elements (3) being composed by polymeric, ceramic, or composite materials.

16) “EMITTER WHEEL ASSEMBLY”, in accordance with claim 1, characterized by an enclosed sensitizer ring (1)′ assembled into a shielded, electrically insulated environment, so as not to lose charge to the environment.

17) “EMITTER WHEEL ASSEMBLY”, in accordance with claim 1, characterized by replacement of the sensitizer ring by a continuous linear element (1)″ incorporating the electrically chargeable elements (3)″ and the non-electrically chargeable spaces (4)″ interleaved and adjacent to the sensor (20).
